(19) United States
(12) Patent Application Publication
(10) Pub. No.: US 2025/0283943 A1
(43) Pub. Date: Sep. 11, 2025

(54) Method of Synchronization of Sensors, Computer Program Product and Computer-Readable Storage Medium

(71) Applicant: ABB Schweiz AG, Baden (CH)

(72) Inventors: Dominik Suszalski, Kraków (PL); Tomasz Zygmunt, Powroznik (PL); Krzysztof Nowakowski, Kraków (PL); Filip Polednia, Bielsko-Biala (PL)

(73) Assignee: ABB Schweiz AG, Baden (CH)

(21) Appl. No.: 19/069,691

(22) Filed: Mar. 4, 2025

(30) Foreign Application Priority Data
Mar. 7, 2024 (EP) 24162086

(51) Int. Cl. G01R 31/34; G01R 1/28; H02K 11/215; H02K 11/35; H02P 29/024

(52) U.S. Cl. CPC G01R 31/343; G01R 1/28; H02K 11/215; H02K 11/35; H02P 29/024

(57) ABSTRACT

A method of synchronization of sensors, each comprising an internal clock, an accelerometer, a magnetic field sensor and a wireless communication means, for monitoring an electrical motor comprising: a. receiving data related to an acceleration and a magnetic field from the sensors, b. calculating, on a basis of a magnetic field and a position of the sensors, a desynchronization time being a difference between the internal clocks of the sensors, c. shifting, by the desynchronization time, the data related to the acceleration from one of the sensors, and d. analyzing of the acceleration data to obtain data related to a vibration phase shift.

### CROSS-REFERENCE TO RELATED APPLICATIONS

The instant application claims priority to European Patent Application No. 24162086.3, filed Mar. 7, 2024, which is incorporated herein in its entirety by reference.

### FIELD OF THE DISCLOSURE

The present disclosure generally relates to a method of synchronization of sensors and, more specifically, sensors that are attached to an electrical motor and that obtain data during phase analysis.

### BACKGROUND OF THE INVENTION

In the prior art, a time synchronization of sensors that are mounted on different parts of a motor, was accomplished by connecting the sensors to the central unit with cables. That is not cost efficient and is prone to failure. The synchronization is also possible to be obtained via external radio signal that synchronizes all the devices in nearby area. That requires both an additional radio sensor to be included and the central unit generating the strong enough synchronization signal.

### BRIEF SUMMARY OF THE INVENTION

The invention proposes using the motor's own magnetic field to synchronize devices mounted on different parts of an induction motor. This method utilizes already used magnetometers and avoids need for cables or an additional radio sensor and radio emitter unit. It is therefore simpler, less prone to failure and cheaper to set up.

A first aspect of the present disclosure describes a method of synchronization of sensors. Each sensor comprises an internal clock, an accelerometer, a magnetic field sensor and a wireless communication device for monitoring an electrical motor. The method includes a. receiving data related to an acceleration and a magnetic field from the sensors, b. calculating, on a basis of a magnetic field and a position of the sensors, a desynchronization time being a difference between the internal clocks of the sensors, c. shifting, by the desynchronization time, the data related to the acceleration from one of the sensors, and d. analyzing of the acceleration data to obtain data related to a vibration phase shift.

### BRIEF DESCRIPTION OF THE SEVERAL VIEWS OF THE DRAWING(S)

FIG. 1 is a diagram of exemplary positions of sensors on a motor in accordance with the disclosure.

FIG. 2 is a graph of data obtained from the sensors on the motor as shown in FIG. 1.

### DETAILED DESCRIPTION OF THE INVENTION

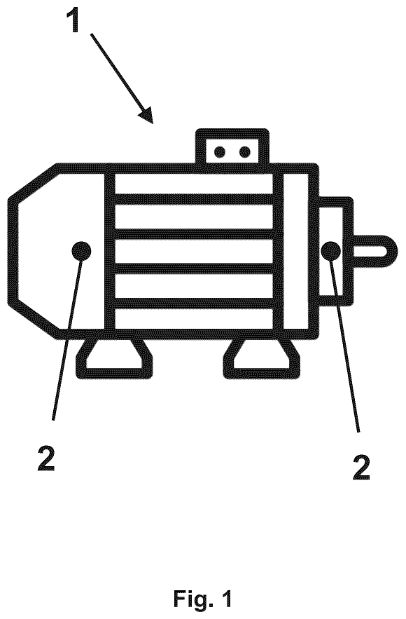

FIG. 1 illustrates an exemplary placement of two sensors 2 that are attached to a motor 1. The sensors 2 are used to measure acceleration, which is a vibration of the motor, so that a phase analysis may be performed.

In monitoring the induction motor 1, knowledge of phase difference between motor bearings is of great importance, as it allows one to identify some types of faults like misalignment or unbalance with high certainty. Nowadays, many various cheap sensors 2 are available on the market that can measure both acceleration and magnetic field at their position. Such sensors 2 use quartz clocks that desynchronize over time, e.g., over a period of one or two weeks, making it impossible to retrieve the vibration phase difference between them. The solution proposes a way to synchronize sensors 2 without a need of cable connection between the sensors 2. The idea is based on presence of rotating magnetic field in the vicinity of an induction motor 1. This field rotates with the same frequency and phase all around the motor 1 making it a great synchronization signal.

A method of synchronization of sensors 2 is thus proposed. The method comprising steps of: a. receiving data related to an acceleration and a magnetic field from the sensors 2, b. calculating, on a basis of a magnetic field and a position of the sensors 2, a desynchronization time dT being a difference between the internal clocks of the sensors 2, c. shifting, by the desynchronization time dT, the data related to the acceleration from one of the sensors, and d. analyzing of the acceleration data to obtain data related to a vibration phase shift.

It should be noted that in the both sensors 2 shown in FIG. 1 are in the same angular position-that is both sensors 2 will measure a peak value of magnetic field at the same time. It should be however noted that the sensors 2 may be in different angular positions—for example 90 or 180 degrees from each other and thus measuring the same peak in a different time. Other values are also possible. In this method it is important to know where those sensors 2 are—they respective position may be used to further determine the desynchronization time dT since peak values of the magnetic field will occur in a different time since both sensors are shifted, by some known angle, from each other.

It should also be mentioned that some steps or all steps may be performed locally, in a cloud or other remote computation unit or a server.

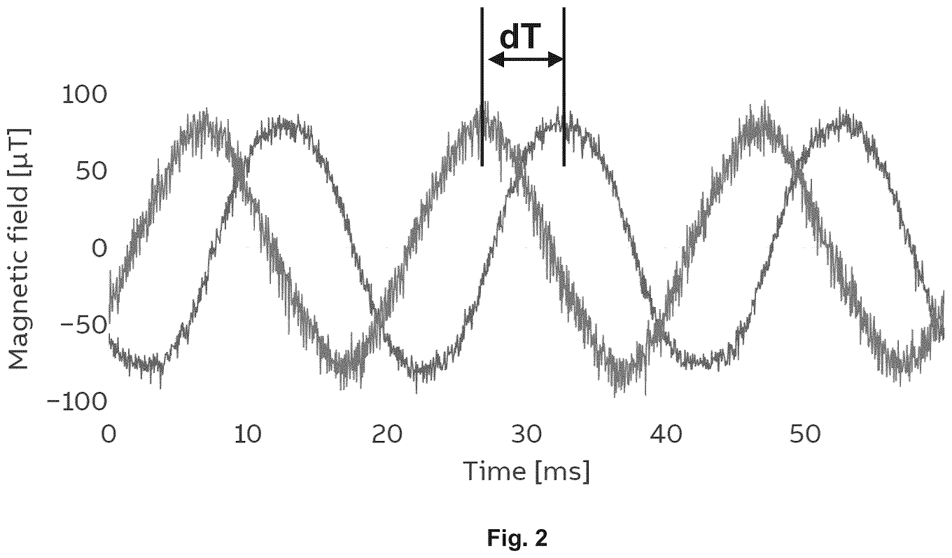

An exemplary data set is presented in FIG. 2. In such example both sensors should measure a magnetic peak value in the same time, which is not true according to data obtained. The difference between both data sets may be used to calculate the desynchronization time dT being a difference between a time of the magnetic peak value measured by both sensors 2.

Experimental data has shown that such method is possible. During an experiment, an expected signal RMS was approx. 140 μT, where a noise RMS was 0.3 μT. Such values allows using the magnetic field of the motor 1 to synchronize sensors 2.

In one embodiment, the method further includes a step e., which is performed after step d., namely when analyzing of the acceleration data indicates that there is a malfunction of the electrical motor 1, an alarm is set.

In another embodiment the position of the sensor 2 is predefined, preferably the position is provided with a precision of approx. +/−5 degrees. Such accuracy may be obtained by a technician without using any equipment. The acceleration data are used to calculate a an exact position of the sensors 2—a gravity may be used to provide a more precise angle between the sensors 2. It should be mentioned that sensors 2 are usually placed close to the bearings of the motor 1 such that each senor 2 is near a different bearing.

In another embodiment, the acceleration data are used to calculate the position of the sensors 2 with minimal prior information regarding positions of the sensors 2. The angle between the sensors 2 is calculated on a basis of the gravity only. It should be noted that both sensors 2 must be in the same position relative to the motor 1 shaft, that is, for example, that both bottom sides of the sensors 2 points toward the shaft. In such a case it is possible to determine which one of the sensors 2 measure the peak magnetic value first. Such approach is possible when the mounting surface is cylindrical. Alternative approach is to trigger the measurement by magnetic field slope. That would be sensitive though to the offset of magnetization if magnetic DC is not removed.

In another embodiment, the method further includes a step f., which includes synchronization of the internal clocks of the sensors 2 that is performed wirelessly, for example, through a Bluetooth protocol. It is done so that the desynchronization time dT is within a limits which assure that obtained data may be used. For example the desynchronization time dT should be lower than 100 ms, even more preferably lower than 8 ms. For obvious reasons a clock synchronization via a wireless communication channel needs to be better that half of a period of a rotation of a motor magnetic field. That is possible with a standard wireless communication. It is expected that such a wireless synchronization will be needed once every 2-3 years at most, usually even every few months.

In the case were the internal clocks of the sensors 2 are desynchronizing in much faster rate such that constant resynchronization is not practical another approach is proposed. In such a case, before step a., step g. is performed during which one of the sensors 2 emits a synchronization signal which cause other sensors 2 to start acquisition of the data related to the acceleration and the magnetic field of the motor 1. It should be noted that such synchronization signal may also be used with better clocks as an additional measure to provide that the data related to the acceleration and the magnetic field of the motor 1 are collected in a time which allows to used said data in further analysis.

A computer program product comprising instructions which, when the program is executed by a computer, cause the computer to carry out the method is another aspect of the disclosure. A computer-readable storage medium comprising instructions which, when executed by a computer, cause the computer to carry out the method is a yet another aspect of the disclosure.

The present disclosure describes using the motor's own magnetic field to synchronize devices mounted on different parts of an induction motor. It takes advantage of already used magnetometers avoiding need for cables or additional radio sensor and radio emitter unit. It is therefore simpler, less prone to failure, and cheaper to set up.

A first aspect of the present disclosure is a method of synchronization of sensors. Each sensor comprising an internal clock, an accelerometer, a magnetic field sensor and a wireless communication means, for monitoring an electrical motor. The method comprising steps of: a. receiving data related to an acceleration and a magnetic field from the sensors, b. calculating, on a basis of a magnetic field and a position of the sensors, a desynchronization time being a difference between the internal clocks of the sensors, c. shifting, by the desynchronization time, the data related to the acceleration from one of the sensors, d. analyzing of the acceleration data to obtain data related to a vibration phase shift.

Step e. can be performed after step d., namely, when analyzing of the acceleration data indicates that there is a malfunction of the electrical motor, an alarm is set.

The position of the sensor is predefined, preferably the position is provided with a precision of +/−5 degrees. The acceleration data are used to calculate the position of the sensors. Step f. is performed, namely, synchronization of the internal clocks of the sensors is performed wirelessly, preferably with a Bluetooth protocol.

Step f. is performed when the desynchronization time is greater than 100 ms, preferably it is greater than 8 ms. Before step a., step g. is performed, during which one of the sensors emits a synchronization signal which cause other sensors to start acquisition of the data related to the acceleration and the magnetic field of the motor.

A second aspect of the present disclosure is a computer program product comprising instructions which, when the program is executed by a computer, cause the computer to carry out the method as described hereinbefore.

A third aspect of the present disclosure is a computer-readable storage medium comprising instructions which, when executed by a computer, cause the computer to carry out the method as described hereinbefore.

A goal of the embodiments in accordance with the disclosure is to provide a method of a synchronization of the sensors without additional equipment and a use of the radio communication such that the system performing the method will be cheap to manufacture and during an exploitation.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method of synchronization of sensors, each of the sensors comprising an internal clock, an accelerometer, a magnetic field sensor and a wireless communication device, the sensors configured for monitoring an electrical motor, the method comprising:
a. receiving data related to an acceleration and a magnetic field from the sensors;
b. calculating, on a basis of a magnetic field and a position of the sensors, a desynchronization time being a difference between the internal clocks of the sensors;
c. shifting, by the desynchronization time, the data related to the acceleration from one of the sensors; and
d. analyzing of the acceleration data to obtain data related to a vibration phase shift.

2. The method according to claim 1, further comprising e. setting an alarm when analyzing the acceleration data indicates that there is a malfunction of the electrical motor.

3. The method according to claim 1, wherein a position of the sensor is predefined.

4. The method according to claim 1, wherein the acceleration data is used to calculate a position of the sensors.

5. The method according to claim 1, further comprising f. wirelessly synchronizing the internal clocks of the sensors.

6. The method according to claim 5, wherein step f. is performed when the desynchronization time is greater than 8 ms.

7. The method according to claim 1, wherein, before step a., a step g. is performed, during which one of the sensors emits a synchronization signal which causes other sensors to start acquisition of the data related to the acceleration and the magnetic field of the motor.

8. A tangible computer-readable storage medium comprising instructions which, when executed by a computer, cause the computer to carry out a method of synchronization of sensors, each of the sensors comprising an internal clock, an accelerometer, a magnetic field sensor and a wireless communication device, the sensors configured for monitoring an electrical motor, the method comprising:
a. receiving data related to an acceleration and a magnetic field from the sensors;
b. calculating, on a basis of a magnetic field and a position of the sensors, a desynchronization time being a difference between the internal clocks of the sensors;
c. shifting, by the desynchronization time, the data related to the acceleration from one of the sensors; and
d. analyzing of the acceleration data to obtain data related to a vibration phase shift.

9. The tangible computer-readable storage medium according to claim 8, further comprising e. setting an alarm when analyzing the acceleration data indicates that there is a malfunction of the electrical motor.

10. The tangible computer-readable storage medium according to claim 8, wherein a position of the sensor is predefined.

11. The tangible computer-readable storage medium according to claim 8, wherein the acceleration data is used to calculate a position of the sensors.

12. The tangible computer-readable storage medium according to claim 8, further comprising f. wirelessly synchronizing the internal clocks of the sensors.

13. The tangible computer-readable storage medium according to claim 12, wherein step f. is performed when the desynchronization time is greater than 8 ms.

14. The tangible computer-readable storage medium according to claim 8, wherein, before step a., a step g. is performed, during which one of the sensors emits a synchronization signal which causes other sensors to start acquisition of the data related to the acceleration and the magnetic field of the motor.
